(19) United States
(12) Patent Application Publication
(10) Pub. No.: US 2024/0170315 A1
(43) Pub. Date: May 23, 2024

(54) CLIP AND LID SYSTEM FOR A CHIP TRAY

(71) Applicant: BAE Systems Information and Electronic Systems Integration Inc., Nashua, NH (US)

(72) Inventors: Richard Rochford, Litchfield, NH (US); Edward L. Brabant, Jr., Dracut, MA (US)

(21) Appl. No.: 18/551,426

(22) PCT Filed: Mar. 28, 2022
(86) PCT No.: PCT/US22/22161

§ 371 Date: Sep. 20, 2023

Related U.S. Application Data
(60) Provisional application No. 63/166,476, filed on Mar. 26, 2021.

(51) Int. Cl. H01L 21/673

(52) U.S. Cl. CPC H01L 21/67333

(57) ABSTRACT

A clip for retaining a chip tray and lid, including in one example a pair of side walls, a rear wall, an upper peripheral edge extending from an upper section of each of the side walls and the rear wall and defining an upper region open area therebetween. A lower peripheral edge extending from a lower section of each of the side walls and the rear wall and defining a lower region open area therebetween. A front opening configured to receive the chip tray and lid. The chip tray has a plurality of pockets configured to hold the semiconductor devices. In one example the lid includes a shock absorbing layer and an electrostatic dissipative layer integrated into an interior of the lid.

### CROSS-REFERENCE TO RELATED APPLICATIONS

This application claims the benefit of U.S. Application Ser. No. 63/166,476 entitled Clip and Lid Systems for a Chip Tray filed Mar. 26, 2021, the entire disclosure of which is incorporated herein by reference. A related application includes U.S. patent application Ser. No. 17/270,534 filed Feb. 23, 2021 which is incorporated by reference for all purposes.

### FIELD

The present disclosure relates generally to securing semiconductor devices in chip tray assemblies, for purposes such as transportation and handling. More particularly, the disclosure relates to a clip used with a lid for securing components in a chip tray.

### BACKGROUND

Integrated circuits (ICs) or semiconductor devices are typically formed as one or more die on a wafer. The semiconductor devices are fabricated on the wafer by a fabrication facility. After being formed on the die, the individual die are cut from the wafer producing a number of small semiconductor components. The semiconductor devices are then shipped to the electronics industry. The semiconductor components are typically mounted to circuit boards, or packaged in some form of enclosure in electronic devices. One common package consists of a substrate upon which the die is mounted along with other components and the larger unit may be any of the electronic units such as cell phones, televisions as well as used in larger systems such as cars, planes, and used in systems that control the electrical grid, communications and defense.

The semiconductor devices are small and fragile and are typically placed in a semiconductor chip tray, commonly referred to as a “waffle pack” for transport. A variety of small electrical devices, including, but not limited to, aforementioned die cut out from wafers are shipped in the waffle packs. Conventional waffle packs include a tray that contains pockets. The die or other electrical devices contained by the waffle pack may be microscopically small, resembling what can be best visualized as “cubic beach sand.” Because various sizes of electrical devices may be contained by a waffle pack tray, the length, width, and depth of the pockets are based on the size of the electrical devices to be contained. The waffle packs can be integrated into automated processes such that the components are automatically placed into the pockets of the waffle pack. They are shipped to the destination in the waffle packs and then subject to internal inspection. The semiconductor devices in the waffle packs may also be transported between facilities and locations before ultimately being integrated into the manufacturing processes.

Each semiconductor component can represent thousands of dollars and the waffle pack can contain hundreds of components. The safety and integrity of these components is paramount as improper transport or handling can cause part failure or impact the longevity of the component when integrated into higher assemblies. These higher assemblies may be involved in critical health, safety and national defense applications. Therefore any migration out of the pocket which could induce damage or the application of too much pressure to the semiconductor components can result in lower yield or field failures.

Typically, a waffle pack is closed by a lid during the transportation process in an effort to prevent migration of the electrical devices contained within the pockets of the waffle pack as well as keep debris and contaminants from contacting these components. However, due to the current waffle pack design, the parts within the pockets of the waffle pack can move about during shipping and handling. This phenomenon of part migration is sometimes referred to as a “die out of pocket” or “component out of pocket.” As device sizes continue to get smaller, thin parts, such as those that are ≤0.010″ are particularly susceptible to migration. The traditional lid is a hard plastic with an interior portion that is intended to mate with the tray and retain the parts. However, owing to flatness tolerances, there tends to be gaps and spaces that allow the parts to move freely even when the lid is placed on the tray. In some cases the interior of the lid may have an adhered rigid foam portion and/or electrostatic dissipative sheets inserted to help keep the components from migrating or acting as a cushion for sensitive parts. Once again, the parts are still subject to migration and movement, and can also have complications from the adhered, rigid foam and inserted sheets caused by misaligned and pinched inserts that create escape paths.

FIGS. 1A and 1B depict a conventional waffle pack system 10 that has a tray or base 20 covered with a lid 30 and retained by a clip 50. The tray 20 has a number of individual compartments or pockets 25 for holding semiconductor components (not shown) such as die. The size, shape and number of pockets 25 are configured according to the design criteria for holding the semiconductor components, but the waffle packs are typically square and in 2 inch and 4 inch sizes. The lid 30 is configured to mate with the base 20 such that the lid interior portion 35 is in close proximity to the semiconductor components in the tray 20. The lid interior portion 35 may include a foam layer integral with the lid interior 35. In some cases an insert (not shown) such as an electrostatic dissipative sheet or rice paper may be placed between the interior portion 35 and the components in the tray 20. An outer lip 40 of the lid 30 mates with a corresponding flange 45 on the tray 20 when retained by the clip 50.

Referring to FIG. 1B, an industry standard clip 50 is depicted wherein the tray 20 and lid 30 are held together and slid into the clip 50 assembly. The side members 80 retain the lid 30 and tray 20 together within the clip 50 and the leaf springs 90 protruding from the base 60 apply pressure to the tray 20 that is in direct contact with the springs 90. As noted, it has been hypothesized that the pressure is not uniform and results in some warping that enables part migration. The clip 50 shown in FIG. 1B is one of several types of clips that have been used as an attempt to seal components within the pockets of a tray covered with the lid. However these assemblies have demonstrated warpage and deformations that permit the components to migrate. Also, in practice, the side members 80 of the conventional clips 30 tend to become worn or break and do not provide uniform or adequate pressure to retain the parts in the proper pockets. Furthermore, based on testing, the conventional clips 50 tend to suffer from fatigue and the side members 80 are prone to failure and in some cases break from repeated use.

Referring to FIG. 2, an x-ray image of the traditional waffle pack tray 20 was taken following a drop test. The tray 20 has 14×14 pockets for holding up to 196 parts and as illustrated, several parts 40 have moved out of the pockets. Based on analyses, the industry standard lids that cover the trays were subject to warpage and deformation that allowed the parts to migrate out of the pockets. The retaining clips that are supposed to retain pressure on the lid to secure it to the tray induce irregular deformation. As described, the compression applied by the clips to the lids is non-uniform and the spacing between the interior of the lid and the pockets allows for part migration and damage to the components. The movement of the parts leads to lower yield and parts that may have a shorter lifespan when placed into electronic devices.

Die and similar electrical devices placed within the waffle packs are generally fragile and/or thin devices, and may also contain delicate sub-structures on their outer surface. For example, air bridges to separate a foil from a conductor line are sometimes present on the surfaces of semiconductors. Parts that become stacked or slide onto each other will cause damage to the parts and lower yield.

A means for securing the lid to the waffle pack is desirable to prevent the lid from becoming dislodged or displaced from the waffle pack during transportation. What is desired is a lid that has satisfactory cushion to secure the components within the pockets to prevent part migration and for a clip that can apply even compression to maintain the lid onto the waffle pack and with the proper compression. Therefore, the hard lid should cover the components and keep them in the pockets but not be compressed against the tray to the point where the lid comes into direct contact with any of the electrical devices contained within the waffle pack.

### SUMMARY

Accordingly, there is a need for an improved device for securing components in a chip tray in order to reduce part migration and optimize efficiency in shipping and handling. Migration can occur because of, among other reasons, loosening of the lid; displacement of an electrostatic dissipative layer between the chip tray and the lid; dropping, shaking or uneven pressure being applied to the chip tray during shipping and handling; and warping of the lid as a result of uneven pressure being applied by a securing device.

An example embodiment of the present disclosure provides a clip for securing a lid for the chip tray. The clip for has a plurality of peripheral side walls. Each of the peripheral side walls has an upper edge, a lower edge. A rear wall also has an upper edge and a lower edge. A front opening is configured to receive the chip tray and lid.

One embodiment is a system for transporting and handling semiconductor devices, including a chip tray having a plurality of pockets configured to hold the semiconductor devices. A lid configured to cover the chip tray, wherein the lid comprises a shock absorbing layer and an electrostatic dissipative layer integrated into an interior of the lid. A clip is configured to retain the chip tray and the lid, wherein the clip comprises a pair of side walls, a rear wall, a top having a flange about each of the side walls and the rear wall and configured to engage with a top of the lid, and a base having a flange about each of the side walls and the rear wall and configured to engage with an underside of the chip tray. There is a front opening configured to receive the chip tray and lid.

Particular embodiments are configured and arranged to apply a uniform downward force between the lid and the chip tray. The front edge of the top integral cover may have a chamfered lip. The top, the bottom, the rear walls and the side walls define a cavity and may be molded as a single unit. The clip may have at least one extruded pin on the top surface of the top.

Implementations of the techniques discussed above may include a method or process, a system or apparatus. The details or one or more implementations are set forth in the accompanying drawings and the description below. Other features will be apparent from the description and drawings, and from the claims.

The features and advantages described herein are not all-inclusive and, in particular, many additional features and advantages will be apparent to one of ordinary skill in the art in view of the drawings, specification, and claims. Moreover, it should be noted that the language used in the specification has been selected principally for readability and instructional purposes and not to limit the scope of the inventive subject matter.

### BRIEF DESCRIPTION OF THE DRAWINGS

FIG. 1A is a perspective view of a tray and lid forming a conventional waffle pack.

FIG. 1B is a perspective view of a clip for the conventional waffle pack.

FIG. 2 is a top view of a chip tray taken by an x-ray inspection following a drop test of the conventional waffle pack.

FIG. 3 is a front view perspective of a clip for securing a lid to a tray according to one embodiment.

FIG. 4A is a front view perspective of a further clip embodiment for securing a lid to a tray according to one embodiment.

FIG. 4B is a front view perspective of the clip embodiment of FIG. 4A showing the waffle pack inserted into the clip according to one embodiment.

FIG. 5 is a top view perspective of another clip embodiment for securing the lid to the tray according to one embodiment.

FIG. 6 shows how the tray and lid are combined with the clip to form the final assembly according to one embodiment.

FIG. 7 shows a front view perspective of the tray and lid retained within a clip embodiment according to one embodiment.

FIG. 7B-D show the system for removing a chip tray from a clip securing a chip tray according to one embodiment.

FIG. 8A illustrates the tray as well as the elements that comprise the lid according to one embodiment.

FIG. 8B is a cut-away view of the tray and components in the pockets with the lid assembly and retained in the clip according to one embodiment.

FIG. 9A shows the lid, tray and clip in isolation and integrated according to one embodiment.

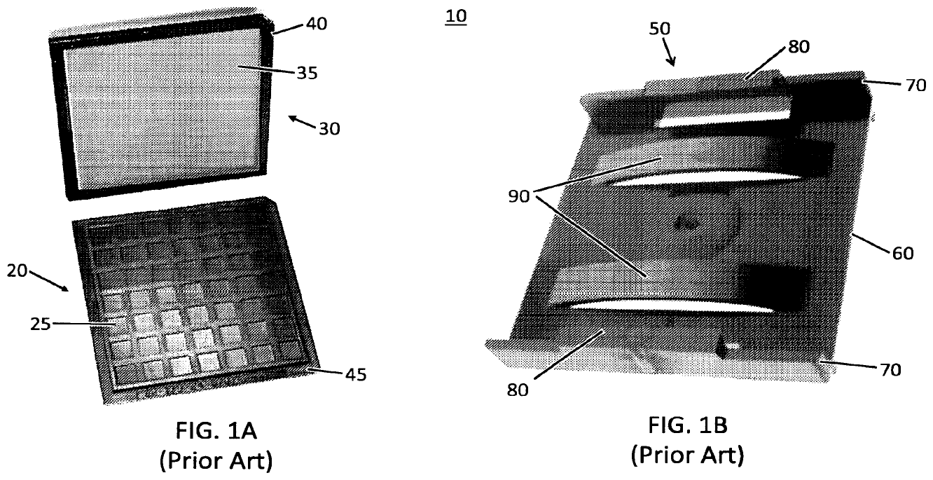

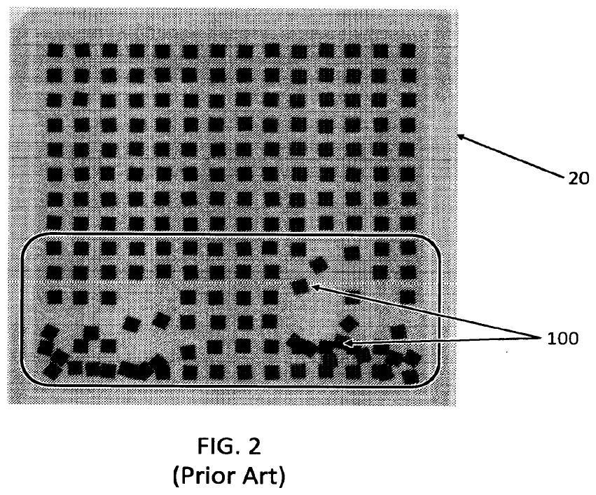

These and other features of the present embodiments will be understood better by reading the following detailed description, taken together with the figures herein described. The accompanying drawings are intended to be drawn to scale. For purposes of clarity, not every component may be labeled in every drawing.

### DETAILED DESCRIPTION

The present disclosure relates to securing components in chip trays with a lid referred to as “waffle packs”, and particularly for securing semiconductor device components. In one example, the present systems relates to a clip for securing a lid to a chip tray (e.g.: waffle pack) for transporting and shipping electrical devices such as semiconductors. The clip secures the lid to the trays to keep the components in the pockets of the tray and preventing and mitigating the displacement or damage of the components by providing sufficient compressive contact.

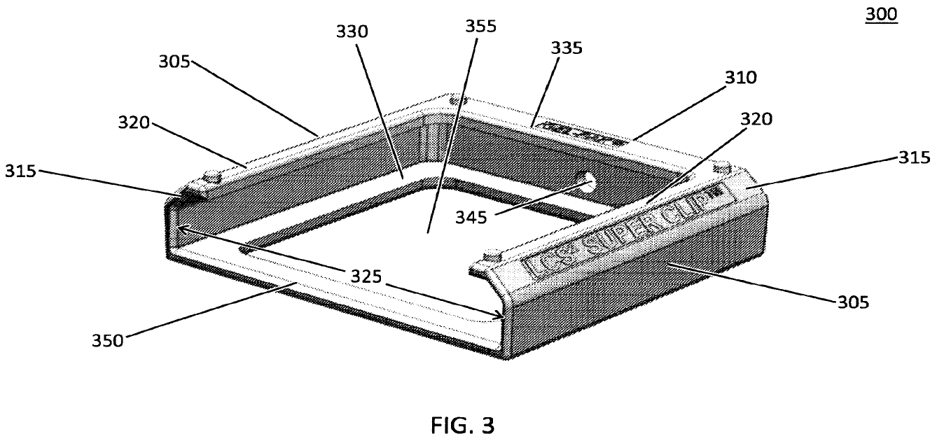

Referring to FIG. 3, one embodiment of the clip 300 for securing a lid to a tray is shown. In this embodiment, the clip 300 has a pair of side walls 305 and a rear wall 310 with the walls extending from a base 330 such that the base and walls are integral. In one example the side walls 305 extend orthogonally from the base 330 and have an angled portion 315 culminating in a side flange or side upper edge 320. The side flange 320 in this example extends from the front opening 325 along the entirety of the side of the clip 300 extending from a front edge at the opening 325 to the rear wall 310. In a further example each side flange 320 is less than the full length of the side. The side flanges 320 are configured to mate with the molded lid allowing the lidded tray to slide into the clip 300.

The rear wall 310 in this example is orthogonal from the base portion 330 and culminating in a rear flange 335. The side flanges 315 and rear flange 335 are configured to retain the lidded tray and apply adequate uniform pressure to retain the parts within the pockets of the tray when the lidded tray is held within the clip 300. The rear wall 310 in one example does not have a rear angled section. In one example the rear wall 310 includes a bore 345 used to eject the waffle pack in a manual, semi-automated or automated operation. In one example, the bore has a radius of less than 0.5 inches to prevent dust and debris from entering the bore 345. In an embodiment, the rear wall 310 includes multiple bores. The multiple bores may be evenly distributed along the rear wall 310 in order to allow systems with different ejection systems.

In this example, the clip 300 has a lower beam 350 that is also part of the base 330 wherein the lower beam 350 extends across the front of the clip. The upper beam is omitted in this example, and the top of the clip 300 is open with the open top portion extending across the side flanges 320 and from the rear flange 335. The base 330 has a cut-out 355 that allows for handling the lidded tray during insertion or removal and to provide for viewing of labels applied to the underside of the tray. The cut-out 355 defines a periphery in the base forming the peripheral edges for the lower beam as well as the peripheral edges on the base 330 for the side walls and rear wall. These peripheral edges can also be referred to as base flanges such that there are a lower beam flange, a pair of base side flanges and a rear base flange. The size of the cutout 355 can vary and thereby changing the size of the periphery edges of the base 330. In one example the base can be solid with no cutout and the lid would have labeling for the devices in the tray as opposed to the underside of the tray.

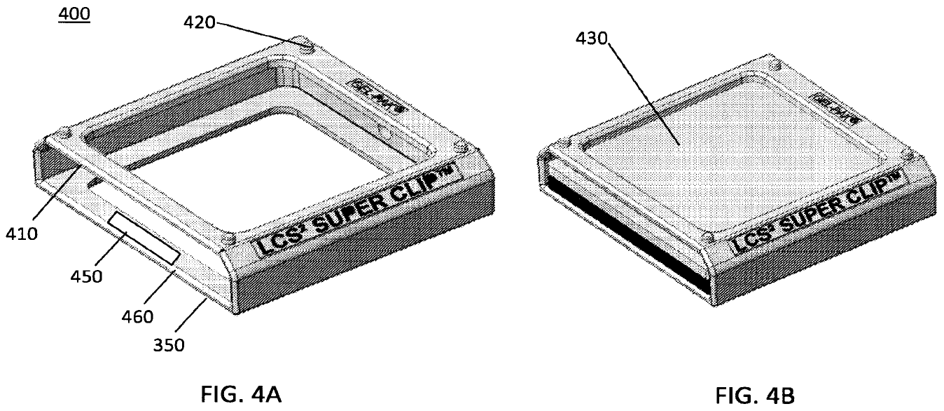

Referring to FIG. 4A, this clip 400 includes the lower beam 350 as well as an upper beam 410 on the front opening. In FIG. 4B, the lidded tray 430 is shown inserted into the clip 400. The clip dimensions provide a friction fit with the lid and tray such that the lid has uniform pressure that keeps the parts in the pockets of the tray. The waffle pack 430 is inserted such the molded lid is flush against the rear wall of the clip such that the sides of the molded lid is in direct contact with the side flanges, the rear of the molded lid is in direct contact with the rear flange, and the front of the molded lid is in direct contact with the upper beam 410. A chamfered front edge 460 at the opening for the lower beam 350 can also reduce or mitigate damage to any labels adhered to the mated chip and lid assembly while being placed into the clip. In a further example, all the front edges are chamfered to facilitate the placement of the tray and lid into the clip.

In one further example, a protrusion 450 is located at the front opening of the clip so that it is easier to confirm the waffle pack is properly positioned within the clip and adds additional protection from the waffle pack being displaced from the clip. The protrusions 450 in one example include one or more bumps, lips or ridges on the front opening such as the lower beam, side walls or upper beam.

According to one example, there are protruding posts 420 located on the corners of the clip 400. These protruding posts are configured to mate with recessed portions located on the underside of other clips permitting the clips to be stacked. The number and location of the protruding posts 420 can be at any location on the top of the clip as long as the recessed portions on the underside of the clips match the locations. The recessed portion is sized to engage with the protruding posts 420. In this example there would be four recessed portions and four corresponding protruding posts 420 so the clips are stackable and enable improved handling and transport. In other embodiments one, two or three protruding posts and corresponding recessed portions are used.

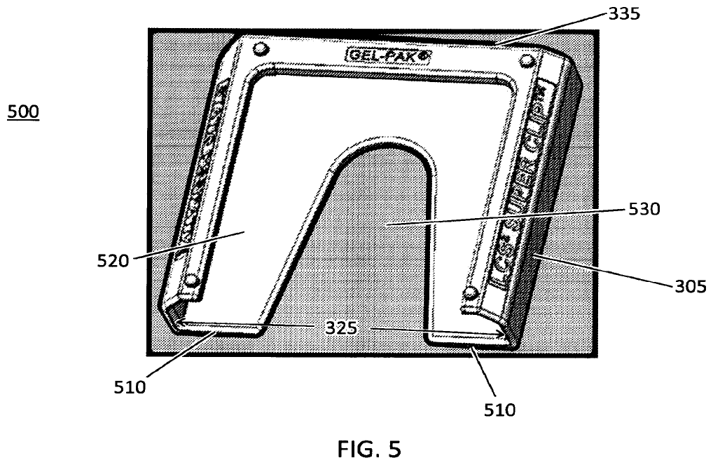

FIG. 5 illustrates a further clip embodiment 500 where the base 520 is configured to form a split lower beam 510 on each side of a front opening 325. The remaining base 520 is integrated with the side walls 305 and the rear wall 335. The split lower beam 510 provides adequate structural support while enabling the lidded tray to be easily inserted and removed without an upper beam and without a full lower beam. The cut-out 530 is configured to enable the easy insertion and removal and in one example of has an oval shape. Other examples of shapes include circular, rectangular, square, polygonic and free form. In one example the shape of the cut-out permits a label on the underside of the tray to be visible. In one example, a cavity is formed from the base, side walls, rear wall, top and base that are integrally coupled together and can be formed from additive manufacturing or injection molding.

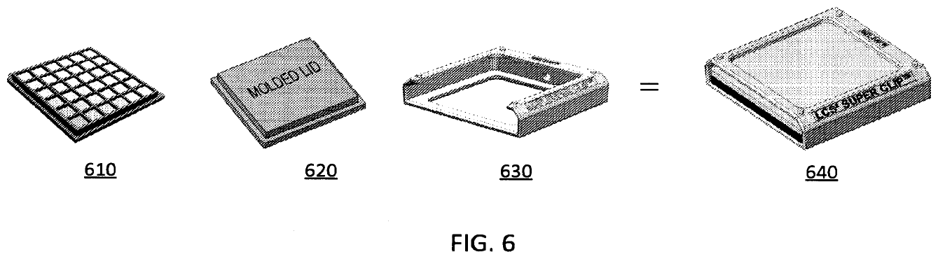

Referring to FIG. 6, the items that make up the semiconductor shipping and handling system is depicted. The tray 610 with pockets sized for the components is filled with the components. A lid 620, such as a molded lid, is placed onto the tray 610. The lidded tray or waffle pack 630 is placed into the clip 630 resulting in the robust system 640 for the components.

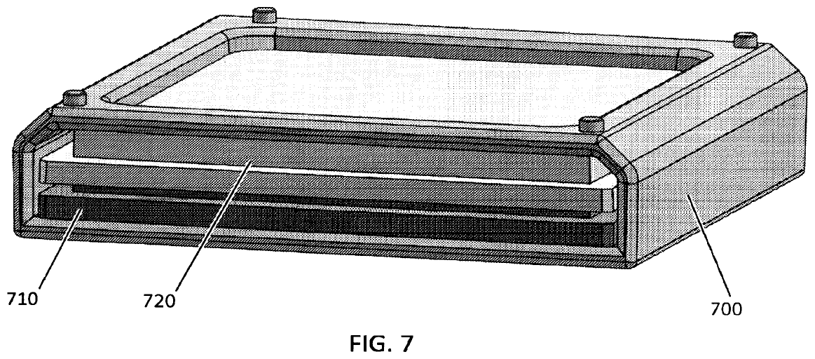

FIG. 7 illustrates the placement of the tray 710 with the lid 720 is slidably engaged within the clip 700. The tray 710 is shown to be in contact with the side walls of the clip 700 with little or no space. This friction fit helps to retain the tray and lid in the clip 700. The lid 720 in this example has a section that is approximately the same dimension as the tray such that the lid 720 is in contact with the side walls. The upper portion of the lid is slightly recessed such that the side edges of the lid are in contact with the side flanges and the rear edge of the lid is in contact with the rear flange. In this example there is an upper beam that contacts the front edge of the lid.

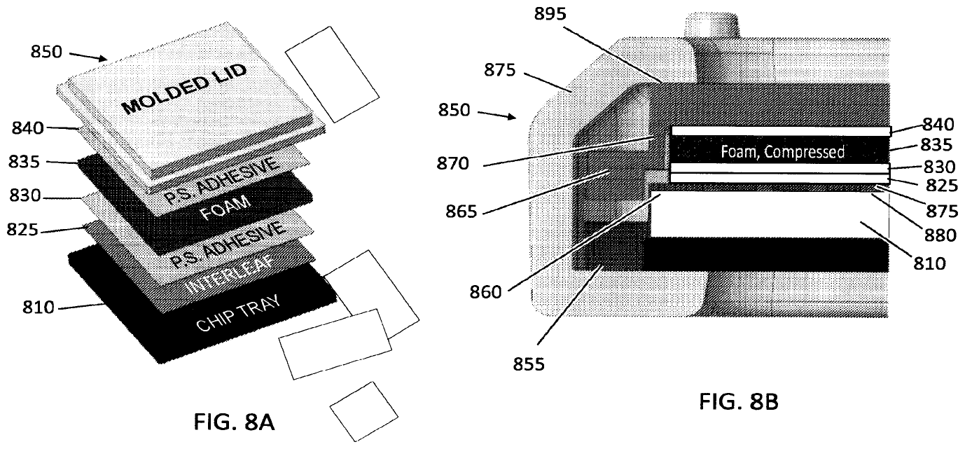

Referring to FIG. 8A, the tray 810 and lid 850 are depicted along with the elements of the lid according to one embodiment. The tray 810 has pockets 875 that are a number of individual compartments for holding electrical devices 880, such as die. The size, shape, and number of compartments are configured according to design criteria for holding the semiconductor components, but typically chip trays are square and in 2-inch and 4-inch sizes. The pockets 875 are normally sized according to the type of electrical device that will be stored therein. In this example there is a recessed void area under the tray 810.

The tray 810 is configured to mate with the lid 850 to form a mated chip tray and lid assembly referred to as a waffle pack. In this embodiments, the lid 850 includes a shock absorbing layer 835 on the interior of the lid 850. The shock absorbing layer 835 may help prevent unevenness along the interior surface of lid 130 when in contact with the pockets and components. The shock absorbing layer 835 may be made of a foam material, such a Rogers Poron® foam. Such foam, normally comprised of polyurethane, provides preferable qualities of compression set resistance, chemical resistance, and can be cleanly cut and used in conjunction with a broad range of adhesives. An adhesive, such as a pressure sensitive adhesive 840 can secure the shock absorbing layer 835 to the interior bottom surface of the lid 850. In one example, an appropriate carbonate material is used as the shock absorbing layer 835. Further, a chamfered front edge at the ingress and/or regress of the clip for securing a chip tray can reduce or prevent such an effect during handling of the material.

One or more electrostatic dissipative layers 825 may be placed between the tray 810 and the lid 850. The electrostatic dissipative layers 825 in one example is a static dissipative interleaf. In one example the layer is made of Tyvek®, a non-woven polyester fiber. Such electrostatic dissipative material also may provide a smoother surface than the foam 835, and mitigate parts sticking to the foam 835. At the same time, the electrostatically-dissipative quality of the material reduces risk of shock by reducing the rate of charge transfer. The electrostatic dissipative layers 825 may alternatively be made of a carbonate material that is naturally electrostatically dissipative, in order to reduce the risk of organic material and/or topical anti-stat compound sloughing off of the Tyvek® sheets onto the electrical devices 880 in the chip tray 810. In one example the electrostatic dissipative layers 825 are secured to the shock absorbing layer 835 by an adhesive 830.

One common misconception in the industry is that these electrostatic dissipative sheets that may be placed into the waffle pack reduce or prevent part migration between pockets of chip trays. Such inserts alone, without being integral with the lid and accompanied with a shock absorbing layer, may not prevent migration or damage of the components. Furthermore, in the conventional usage where an electrostatic dissipative sheet is merely inserted into the waffle pack without being integrated into the lid, the sheets have a tendency to become displaced or wrinkled during the placement or during shipping and handling. Further, materials such as Tyvek® may stick when come in contact with finger cots that are used during handling/assembly, which can cause additional displacement or damage to the components. In contrast, as noted herein, the electrostatic dissipative layer 825 is an integral part of the lid along with the conformal shock absorbing foam layer 835. Additional details of the lid features may be found in published PCT application WO2020106877A1, the entire contents of which are incorporated by reference herein in their entirety and for all purposes.

Referring to FIG. 8B, a sectional view of the waffle pack and clip is depicted. The clip 850 houses the tray 810 and lid 850. The flange 855 of the tray is supported by the base of the clip. There is a recessed portion of the tray 860 wherein the pockets 875 and components 880 reside. A clip flange 865 overlaps the recessed portion of the tray 860 and mitigates against foreign debris from being deposited on the tray. A recessed portion of the lid 870 provides an interior space in the lid for the shock absorbing layer and electrostatic dissipative layer 825. The upper surface of the lid 895 contacts with the clip to apply pressure on the lid so that the elements of the interior of the lid secure the devices in the pockets.

In one example the angled section 875 makes the clip easier to manage and facilitates the molding process. The clip design in this example creates a void area. In one example the angle section is molded to conform to the shape of the molded lid and the void area would be filled with material and part of the clip thereby in contact with the top surface of the flange 865 as well as the side surface of the recessed portion 870.

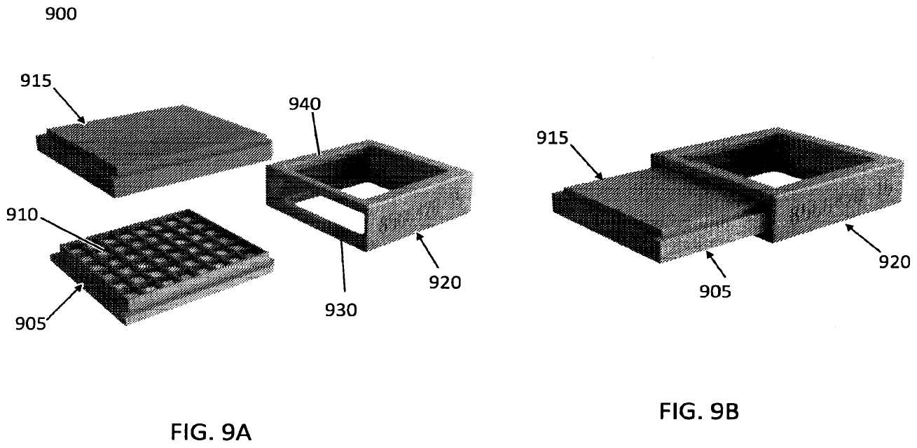

FIGS. 9A and 9B illustrate yet a further embodiment of the present system. The chip tray 905 has a plurality of pockets 910 to house components (not shown) and is configured to mate with the lid 915 to seal the tray from foreign debris and to maintain the components in the pockets. The lid 915 is placed onto the tray 905 forming a lidded chip tray that is inserted the clip 920 wherein the clip in this example has openings in both the top and the base. The clip in this example has base peripheral edges 930 that includes a lower beam flange, a pair of base side flanges and a base rear flange that are configured to contact the bottom of the tray. Likewise the clip has top peripheral edges 940 that includes a top beam flange, a pair of top side flanges and a top rear flange that are configured to contact the top of the lid. There are upper and lower beams at the front of the clip that work in coordination with the side flanges and rear flange to apply pressure to the top of the lid and to the underside of the tray. Once the lidded tray is inserted into the clip, the base peripheral edges contact the underside of the tray and the top peripheral edges contact the top surface of the clip, wherein the clip applies adequate pressure to retain the lidded tray in the clip and retain the components in the pockets.

One advantage of the present clip is that it is not subject to the fatigue and malfunctions associated with repeated use that is evident in conventional clips. The present clip can be used indefinitely without suffering from fatigue that impacts clearance or from breakage due to repeated usage. The clip and lid system detailed herein has been subjected to drop tests and “paint shaker” vibration with no part migration or part failures.

The waffle pack and clip material may be selected so as to reduce or eliminate triboelectric charging. Triboelectric charging is a type of contact electrification on which certain materials become electrically charged after they are separated from a different material with which they were in contact. As an example, a static-dissipative materials can be employed. In an embodiment, RTP® Polymers may be used as the material for lid and tray. In another embodiment, PermaStat® Plus 600 Acrylonitrile Butadiene Styrene (ABS) may be used as materials for the clip. In another embodiment the molded article is from a conductive polycarbonate instead of the static-dissipative.

In an embodiment of a system for calculating the optimal nominal compression, a method is performed at a server system including one or more processors and memory storing one or more programs for execution by the one or more processors. The method may include inputting the surface area of the chip tray pockets, inputting the number of chip tray pockets, inputting a lattice structure according to the pocket layout and/or the basis matrix of such lattice structure, inputting various nominal compression values, inputting the materials of the surface layer and/or foam layer material of the shock absorbing layer, and calculating a range of potential protrusion resulting from applying the various nominal compression values of the shock absorbing layer against the chip tray's pockets. The method may also be performed by making similar calculations by isolating a single pocket of the chip tray and calculating the nominal compression of the shock absorbing layer against the isolated pocket.

Outgassing may be a concern for electronic equipment intended for use in high-vacuum environments. It refers to the release of gas trapped within a solid, such as a high frequency circuit-board material. The effects of outgassing can impact a wide range of application areas, from satellites and space-based equipment to medical systems and equipment, or an electronic device that is to be used, tested, or fabricated in a “clean room.” One measure that can be taken to reduce or prevent outgassing is to include a carbonate layer as an electrostatic dissipative layer and between the chip tray and the lid.

There can be a chamfer on the front edges of the clip. The chamfer(s) may provide for easier assembly of the system for securing a chip tray by allowing for the mated chip tray and lid assembly to more easily slide into position within clip. The benefit(s) of such a chamfer may include reducing or eliminating damage to labels attached the chip tray.

In an embodiment, the shock absorbing layer can be comprised of one layer of double-sided adhesive layers, one layer comprised of a low solvent content, silicone-free PSA and compliant open-cell polyurethane foam, and then another double-sided adhesive layer. In an embodiment the three layers are arranged in series. In an embodiment, the two double-sided adhesive layers may be substantially identical. In an embodiment, both of the double-sided adhesive layers are Nitto® double-sided tape.

In an embodiment, the foam of the shock absorbing layer used inside the lid may be a low solvent content, silicone-free PSA and compliant open-cell polyurethane foam. In one example the material is Rogers® Poron VS-type, an open-cell polyurethane foam. Such material provides for relatively low outgassing while also providing a nominal compression against the chip tray when the mated chip tray and lid assembly is placed inside of the clip for securing a chip tray. Rogers® Poron foam sheets generally have a tolerance of 0.0092 inches. In an embodiment, the range of thicknesses of the Poron foam is approximately between 0.009 and 0.0102 inches. In one example the thickness tolerance is about 0.093″ nominal, +/−7.5%.

In an embodiment, the density of the foam may be 320 kilograms per cubic meter. The thickness of the foam may be selected so that the nominal compression of the foam against the chip tray is between 0.004 and 0.008 inches, and preferably 0.0068 inches. In an embodiment, the height of the cavity can be adjusted to account for the outer edges of the tolerance boundaries of the Poron® foam layer. In an embodiment the tolerance boundaries of the Poron® foam layer are between plus or minus 0.005 inches and 0.0015 inches. In one embodiment the tolerance boundaries of the Poron® foam layer are less than 0.001 inches.

In various embodiments, double-sided or “double-coated” adhesive attaches to the polyurethane open-cell Poron foam of the shock absorbing layer to limit outgassing of hydrocarbons and other organic matter onto the chips within the chip tray. This may reduce or eliminate the impurity of future welds between the chip and another metal, thereby increases the effectiveness of the weld and the resulting connection. In an embodiment, the thickness of the double-side adhesive is 0.00196 inches. In alternative embodiments the thickness of the double-sided adhesive is between 0.003 inches and 0.0137 inches. In various embodiments, the adhesive strength of the double-sided adhesive is between 23 ounces per inch squared (oz./in²) and 109 ounces per inch squared (oz./in²). In an embodiment the double-sided adhesive is Nitto® double-sided tape. In an embodiment the double-sided adhesive has a carrier type of non-woven tissue or non-woven fabric. In other embodiments the carrier type is polymer foam.

As noted in the Table A below, the materials commonly used for tray and lids is shown along with the tray sizes and industry tolerances. As noted herein, the implementation of the present system, especially with the lid assembly used with the clip described herein, cure the aforementioned waffle pack problems.

| | Dimensions and Tolerances | | |
|---|---|---|---|
| Description | Overall Size (sq.) | Overall Height | Flatness |
| Acrylonitrile | 50.8 ± 0.102 mm | 3.96 + 0.051 mm − | 0.102 mm |
| Butadiene | (2.000 ± 0.004″) | 0.076 mm (0.156 + | (0.004″) |
| styrene with a | | 0.002″ − 0.003″) | |
| color additive | | | |
| Polypropylene | 50.673 ± 0.254 mm | 3.937 + 0.076 mm − | 0.305 mm |
| with carbon | (1.995 ± 0.010″) | 0.127 mm (0.155 + | (0.012″) |
| powder and | | 0.003″ − 0.005″) | |
| glass bead | | | |
| Alloy of | 50.8 ± 0.102 mm | 3.96 + 0.051 mm − | 0.102 mm |
| ABS and an | (2.000 ± 0.004″) | 0.076 mm (0.156 + | (0.004″) |
| intrinsically | | 0.002″ − 0.003″) | |
| dissipative | | | |
| polymer | | | |
| Polycarbonate | 50.8 ± 0.102 mm | 3.96 + 0.051 mm − | 0.102 mm |
| with carbon | (2.000 ± 0.004″) | 0.076 mm (0.156 + | (0.004″) |
| powder | | 0.002″ − 0.003″) | |

The clip for securing the waffle pack in one example may be comprised of a material having a surface resistivity of greater than 10⁶ ohms. The clip in one example may be comprised of material having a specific gravity of 0.006 ft³/slug. The flexural modulus may be at least 0.2×10⁶ pounds per square inch (PSI) and the tensile strength may be at least 5,000 PSI.

In one embodiment the protruding pins and corresponding matching receptacles may be configured in a “keyed arrangement.” In such an arrangement, one of the extruded pins is offset slightly from the other three pins relative to the respective corner that is closest to the pin. In various embodiments, the keyed pin may be in the front right corner of the clip for securing a chip tray from a front perspective view of the pin. As an illustrative example, the keyed pin may be 0.25 inches from the front edge of the clip, and 0.15 inches from the right side edge of the clip for securing a chip tray. The other three non-keyed pins are 0.15 inches from each of the edges adjacent to them. This would allow to distinguish components or waffle packs so that certain groups of waffle packs had certain types of components. Using keying and/or color coding in one example would facilitate incoming inspection such that waffle packs could be quickly directed the appropriate location.

According to one embodiment, an anti-tamper label is adhered to the clip. In various embodiments, such an anti-tamper label is configured and arranged to cover the clip and may change colors upon detection of an external force applied thereto. In various embodiments, the anti-tamper label is comprised of acrylic material. Employing known anti-tamper techniques, the integrity of the components can be confirmed such that no tampering occurred during the shipping process.

The dimensions for the clip are configured in order to friction fit the tray and lid to provide sufficient compression of the lid to the compartments to avoid part migration. In a further embodiment the front edges may contain one or more small ridges or bumps on any of the front edges to ensure the lidded chip trays remain in the clip during transit.

In many instances, it is useful to view the top and/or bottom of the waffle pack for information about the devices within the waffle pack. In one embodiment, additional cut-out regions on the top and/or bottom can allow greater area for viewing of the information displayed on the waffle pack whether printed on the waffle pack or on a label. In one example, the label is designed to fit within the cut-out regions.

The sizing of the interior dimensions of the clip in one embodiment is to allow for a friction fit of the waffle pack so that it is maintained within the clip and does not easily slip out. In one further example, a protrusion is located at the front of the clip so that it is easier to confirm the waffle pack is properly positioned within the clip and adds additional protection from the waffle pack being displaced. The protrusions in one example include one or more bumps, lips or ridges on the front opening such as the lower beam, side walls or upper beam. Open areas on the clip's top and bottom will permit access for the application of identifying labels to lid and tray.

According to one example, the clip is injection molded as an integral unit in order to reduce cost of an individual unit. The clip can be a plastic material such as a polycarbonate or antistatic acrylonitrile butadiene styrene with ESD protection. In one example, the material is Permastat Plus 600. In one example, the plastic material is relatively clear or otherwise translucent such that any information on the waffle pack is visible without having to rely on large cut-out regions.

The industry standard sizes of the waffle pack tend to be 2 inch and 4 inch sizes and generally square. However other sizes and shapes such as 6 inch or 8 inch as well as rectangular are within the scope of the teachings presented herein. Thin die such as less than 250 micron present particular industry challenges for pocket migration that are resolved with the present designs and increase overall yield of critical components.

Electrostatic discharge is the sudden flow of electricity between two electrically charged objects caused by contact, an electrical short, or dielectric breakdown. Different devices have different levels of sensitivity to electrostatic discharge. Thus, there needs to be a way to distinguish ESD-sensitive devices from those which are not as vulnerable to ESD. The ESD sensitivity is conventionally specified in terms of the highest ESD test voltage that it passes, and the lowest ESD test voltage that it fails per ESD model. A Class 0 device has a voltage range of less than 250 volts. A class 1A device has a voltage range of between 250 and 500 volts. In various embodiments, the clip for securing a lid to a chip tray may be an electrostatic discharge (ESD) Class 0 device. An ESD Class 0 device is generally thought to be compatible with components that are the most sensitive to electrostatic discharge. In one embodiment, the clip is comprised of a colored material which indicates that it is an ESD Class 0 device.

In an embodiment, the color of the clip is gold. The lid and/or tray may also be gold colored. In one example, the removal of the chip trays from the clip is performed in an automated fashion with a system including one or more processors and memory storing one or more programs for execution by the one or more processors. A robotic arm would place the place the clip unit into position and a control system would engage the removal tool to push the lidded chip tray from the clip. A robotic arm would then remove the lid exposing the electronic devices. Further robotics would select the electronic devices and remove them from the chip tray and perform subsequent operations and assembly with the electronic device. Vision systems such as cameras would be used for orientation to ensure guidance and control of the robotics as well as identify any problems. The vision system could also be used for inventory management as it would read the labels on the chip trays which would be visible in the openings in the clip to count the parts and track by serial number and manufacturing lot identifiers.

The method may include controlling a means for moving a dowel or similar device in a horizontal direction into the bore or plurality of bores defined in the rear peripheral side wall. The method may control a servomotor configured and arranged to actuate such horizontal movement, and/or compressible springs. The method may include a controlling a means for gripping the clip.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

1. A clip for retaining a chip tray and lid, comprising:
a pair of side walls;
a rear wall;
an upper peripheral edge extending from an upper section of each of the side walls and the rear wall and defining an upper region open area therebetween;
a lower peripheral edge extending from a lower section of each of the side walls and the rear wall and defining a lower region open area therebetween; and
a front opening configured to receive the chip tray and lid.

2. The clip according to claim 1, further comprising a lower beam extending across the front opening and integrally coupled to the lower peripheral edge.

3. The clip according to claim 1, further comprising an upper beam extending across the front opening and integrally coupled to the upper peripheral edge.

4. The clip according to claim 1, further comprising a lower beam extending across the front opening and integrally coupled to the lower peripheral edge and an upper beam extending across the front opening and integrally coupled to the lower peripheral edge.

5. The clip according to claim 1, further comprising an angled section on each of the side walls proximate the upper section.

6. The clip according to claim 1, wherein the lower region open area has a substantially same size as the upper region open area.

7. The clip according to claim 1, further comprising at least one chamfered edge at the front opening of at least one of the side walls, the lower peripheral edge and the upper peripheral edge.

8. The clip according to claim 1, further comprising at least one bore in the rear wall.

9. The clip according to claim 1, wherein the lid comprising at least one of a shock absorbing layer and an electrostatic dissipative layer integrated in the lid.

10. The clip according to claim 1, wherein the clip is an integral unit formed by injection molding or additive manufacturing.

11. The clip according to claim 1, wherein the clip is substantially translucent or colored.

12. A system for transporting and handling semiconductor devices, comprising:
a chip tray having a plurality of pockets configured to hold the semiconductor devices;
a lid configured to cover the chip tray, wherein the lid comprises at least one of a shock absorbing layer and an electrostatic dissipative layer integrated into an interior of the lid; and
a clip configured to retain the chip tray and the lid, the clip comprising:
a pair of side walls;
a rear wall;
a top having a flange about each of the side walls and the rear wall and configured to engage with a top of the lid;
a base having a flange about each of the side walls and the rear wall and configured to engage with an underside of the chip tray; and
a front opening configured to receive the chip tray and lid.

13. The system according to claim 12, further comprising one or more protruding posts on the top and one or more recessed portions on the base.

14. The system according to claim 12, further comprising an open region in at least one of the top and the base for viewing a label applied to at least one of the lid or the chip tray.

15. The system according to claim 12, further comprising at least one of a lower beam extending across the front opening and integrally coupled to the base and an upper beam extending across the front opening and integrally coupled to the top.

16. The system according to claim 12, wherein the clip provides a friction fit and compression on the lid and chip tray.

17. A clip for retaining a chip tray and lid holding a plurality of semiconductor components, comprising:
a pair of side walls, each of the side walls having a side flange extending from an upper side section and a lower side section;
a rear wall having a rear flange extending from an upper rear section and a lower rear section, wherein the rear wall is integrally coupled to the side walls;
a base formed from the lower side section of each side flange from and the lower rear section from the rear flange;
a top formed from the upper side section of each side flange from and the upper rear section from the rear flange;
a cavity formed from integrally coupling the side walls, rear wall, top and base; and
a front opening configured to receive the chip tray and lid into the cavity.

18. The clip according to claim 17, further comprising an anti-tamper label substantially covering the clip.

19. The clip according to claim 17, further comprising at least one of a lower beam extending across the front opening and integrally coupled to the base and an upper beam extending across the front opening and integrally coupled to the top.

20. The clip according to claim 17, further comprising an open region in at least one of the top and the base for viewing a label applied to at least one of the lid or the chip tray.
